(19) United States
(12) Patent Application Publication
(10) Pub. No.: US 2026/0259265 A1
(43) Pub. Date: Sep. 3, 2026

(54) Multi-Remote Circuit Breaker Finder

(71) Applicant: Klein Tools, Inc., Lincolnshire, IL (US)

(72) Inventors: David Worden, Vernon Hills, IL (US); Amy Hart, Arlington Heights, IL (US); Alex M. Petty, Des Plaines, IL (US); Quinten Dahlhauser, Kokomo, IN (US)

(73) Assignee: Klein Tools, Inc., Lincolnshire, IL (US)

(21) Appl. No.: 19/554,169

(22) Filed: Mar. 2, 2026

Related U.S. Application Data
(60) Provisional application No. 63/766,186, filed on Mar. 3, 2025.

(51) Int. Cl. G01R 31/327; G01R 1/02; G01R 1/067; G01R 1/073; G01R 19/00

(52) U.S. Cl. CPC G01R 31/3277; G01R 1/025; G01R 1/06788; G01R 1/073; G01R 19/0038; G01R 19/0084

(57) ABSTRACT

A multi-remote circuit breaker finder system is provided. The circuit breaker finder system includes a receiver including a receiver wireless module and an antenna circuit configured to detect a signal at a circuit breaker panel. The system includes a plurality of transmitter devices, each transmitter device configured to couple to a receptacle and including a signal generator configured to send the signal through the receptacle onto a circuit connected to the receptacle. Each transmitter device of the plurality of transmitter devices includes a transmitter wireless module configured to communicate with the receiver wireless module. The receiver is configured to communicate with the plurality of transmitter devices and to indicate detection of the signal corresponding to a selected transmitter device.

### CROSS-REFERENCE TO RELATED APPLICATIONS

This patent application claims priority of U.S. Provisional Patent Application 63/766,186, filed Mar. 3, 2025, the entire contents of which is herein incorporated by reference.

### BACKGROUND OF THE DISCLOSURE

The present disclosure relates to circuit breaker finders and, more specifically, to a circuit breaker finder with multiple remotes. Conventional circuit breaker finders traditionally have a single remote or transmitter that transmits a signal through a circuit and to a circuit breaker. A user may use a receiver to detect the signal, transmitted through the circuit, at a circuit breaker to determine the circuit breaker that corresponds to the circuit connected to the remote transmitter. However, it may be time consuming to use a single remote transmitter to map multiple circuits to the circuit breaker. It is desirable to provide a circuit breaker finder to overcome this issue, improving the speed at which a user map multiple circuits to a circuit breaker.

### BRIEF SUMMARY OF THE DISCLOSURE

In accordance with one feature of this disclosure, a circuit breaker finder system is provided. The circuit breaker finder system includes a receiver including a receiver wireless module and an antenna circuit configured to detect a signal at a circuit breaker panel. The system includes a plurality of transmitter devices, each transmitter device configured to couple to a receptacle and including a signal generator configured to send the signal through the receptacle onto a circuit connected to the receptacle. Each transmitter device of the plurality of transmitter devices includes a transmitter wireless module configured to communicate with the receiver wireless module. The receiver is configured to communicate with the plurality of transmitter devices and to indicate detection of the signal corresponding to a selected transmitter device.

In one feature, the signal is a pulse signal.

As one feature, each transmitter device includes at least one user input configured to set a transmitter identifier for the transmitter device. The receiver is configured to display the transmitter identifier of at least one transmitter device connected to the receiver via a wireless data connection.

In another feature, the transmitter identifier is an ID number.

According to one feature, the receiver includes user input buttons, and the receiver is configured to scroll through transmitter identifiers of the plurality of transmitter devices connected to the receiver.

In yet a further feature, the receiver is configured, in response to selection of a first transmitter device of the plurality of transmitter devices, to send a message to the first transmitter device to enable sending of the pulse signal over a first circuit connected to the first transmitter device.

In one feature the receiver is configured, in response to selection of a second transmitter device of the plurality of transmitter devices, to send a message to the first transmitter device to stop sending the pulse signal over the first circuit and to send a message to the second transmitter device to start sending the pulse signal over a second circuit connected to the second transmitter device.

As another feature, the receiver includes a display and is configured to display a signal strength corresponding to a detected pulse signal.

In one feature, each transmitter device includes voltage measurement circuitry configured to measure a voltage of the receptacle and to provide a measured-voltage signal to a microprocessor of the transmitter device.

As one feature, each transmitter device includes a ground-fault circuit interrupter (GFCI) test circuit configured to provide a signal to the receptacle to test GFCI protection of the receptacle.

In another feature, each transmitter device includes a GFCI button coupled to the GFCI test circuit to trigger the GFCI test circuit.

According to one feature, the receiver is configured to send a signal to a selected transmitter device via the wireless data connection, and the selected transmitter device is configured to trigger the GFCI test circuit based on the signal received from the receiver.

In yet a further feature, the receiver is configured to receive, via a two-way wireless data connection, circuit information from a selected transmitter device, and to display at least a portion of the circuit information on a receiver display.

In one feature, the circuit information includes at least one of voltage information, wiring condition information, and GFCI information.

As another feature, the receiver is configured to provide a user-notification output indicating detection of the pulse signal using at least one of a display, a light emitting diode (LED), and a buzzer.

As one feature, each transmitter device includes a transmitter display configured to display receptacle status information including at least one of voltage information, wiring condition information, and GFCI information.

In another feature, each transmitter device includes a microprocessor configured to provide an on/off control signal to the pulse generator to selectively enable and disable generation of the pulse signal.

In accordance with one feature of this disclosure, a method of identifying a circuit breaker corresponding to an energized receptacle includes coupling a first transmitter to a first energized receptacle, the first transmitter including a pulse generator and a wireless module. The method includes wirelessly connecting the first transmitter to a receiver including a receiver wireless module and an antenna circuit configured to detect a pulse signal at a circuit breaker panel. The method includes using the receiver to select the first transmitter. The method includes, in response to selecting the first transmitter, causing the first transmitter to send, via the pulse generator, a pulse signal through the first energized AC receptacle onto a circuit associated with the first energized AC receptacle. The receiver indicates detection of the pulse signal at a circuit breaker panel to identify a circuit breaker corresponding to the first energized AC receptacle.

In another feature, the method further includes coupling a second transmitter to a second energized receptacle, wirelessly connecting the second transmitter to the receiver, and selecting, via the receiver, the second transmitter while the first transmitter remains wirelessly connected to the receiver.

In a further feature, the method includes determining, at the receiver, a signal-strength metric corresponding to the detected pulse signal, and outputting, via a user-notification output of the receiver, an indication of the signal-strength metric.

### BRIEF DESCRIPTION OF THE DRAWINGS

FIG. 1 is a front view of a circuit breaker finder.

FIG. 2 is a side view of the circuit breaker finder of FIG. 1.

FIG. 3 is a front view of a transmitter from the circuit breaker finder of FIG. 1.

FIG. 4 is a block diagram for the transmitter of FIG. 3.

FIG. 5 is a top view and a side view of a receiver from the circuit breaker finder of FIG. 1.

FIG. 6 is a block diagram for the receiver of FIG. 5.

FIG. 7 shows the circuit breaker finder of FIG. 1 with an exemplary circuit breaker and accompanying circuits.

FIG. 8 is an exemplary flow chart for use of the circuit breaker finder of FIG. 1.

### DETAILED DESCRIPTION OF PREFERRED EMBODIMENTS

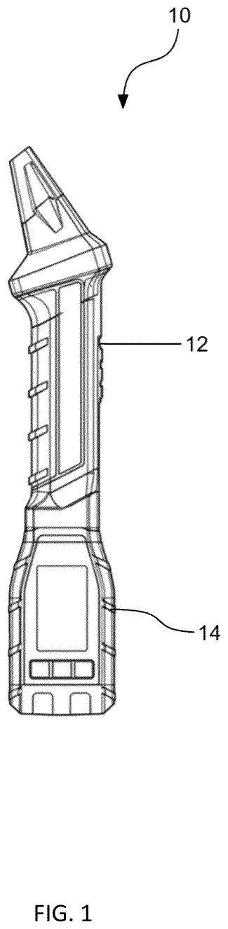

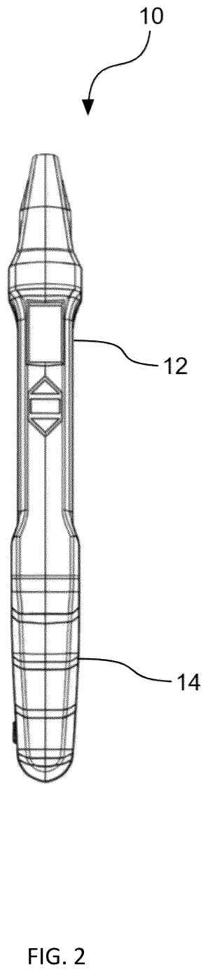

As best shown in FIGS. 1-2, a circuit breaker finder 10 is provided. In the illustrated and preferred embodiment, the circuit breaker finder 10 includes a receiver 12 and a transmitter 14 (e.g., remote). In the illustrated and preferred example, the receiver 12 is connectable (e.g., may be docked) to the transmitter. In some examples, their may be no electrical connection between the docked receiver and transmitter. In some examples, the docked receiver and transmitter may have an electrical connection therebetween.

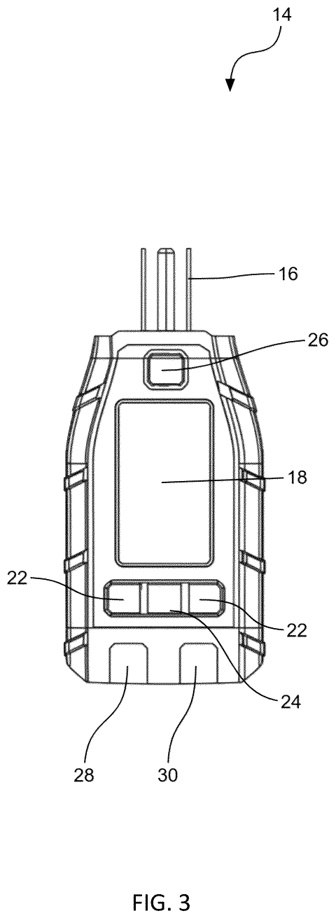

As best shown in FIG. 3, the transmitter 14 includes a plug 16 shown in the form of a Type B (Nema A5-15) (e.g., North American 3-pin plug). In some examples, other plug types may be used. In some examples, the plug may take different forms to connect to a lamp socket. In some examples the plug may include clips such as alligator clips to connect directly to wires. The transmitter 14 includes a circuit and microprocessor for testing circuits connected to an electrical outlet through the plug 16. The transmitter 14 may, for example, measure the circuit voltage, detect and identify wiring conditions (e.g., faults), and test ground-fault circuit interrupter (GFCI). The transmitter 14 includes a transmitter display 18 shown in the form of an LCD display. The transmitter display 18 may indicate the determined (e.g., measured) receptacle status (e.g., voltage, wiring conditions, GFCI information, etc).

In the illustrated and preferred embodiment, the transmitter 14 includes two ID buttons 22, a GFCI button 24, and power button 26. The transmitter 14 includes status light emitting diodes (LEDs) including a correct indicator 28 shown in the form a green LED and a fault indicator 30 shown in the form of red LED. The correct indicator 28 indicates that the transmitter 14 has determined that the connected outlet is correctly wired and the fault indicator 30 indicates that the transmitter 14 has determined that the connected outlet has a wiring fault.

In the illustrated and preferred embodiment, the transmitter includes a pulse generator and a wireless module shown in the form of a Long Range (LoRa) wireless module. While a LoRa is shown, other wireless modules, as are known in the art, may be used. Examples include Wi-Fi, Bluetooth, SigFox, DASH7, NB-IoT, LTE-M, Wi-Fi HaLow, and Zigbee. In the illustrated and preferred embodiment, the transmitter 16 includes a pulse generator. The pulse generator is configured to send a pulse signal through the plug 16 and to a connected circuit.

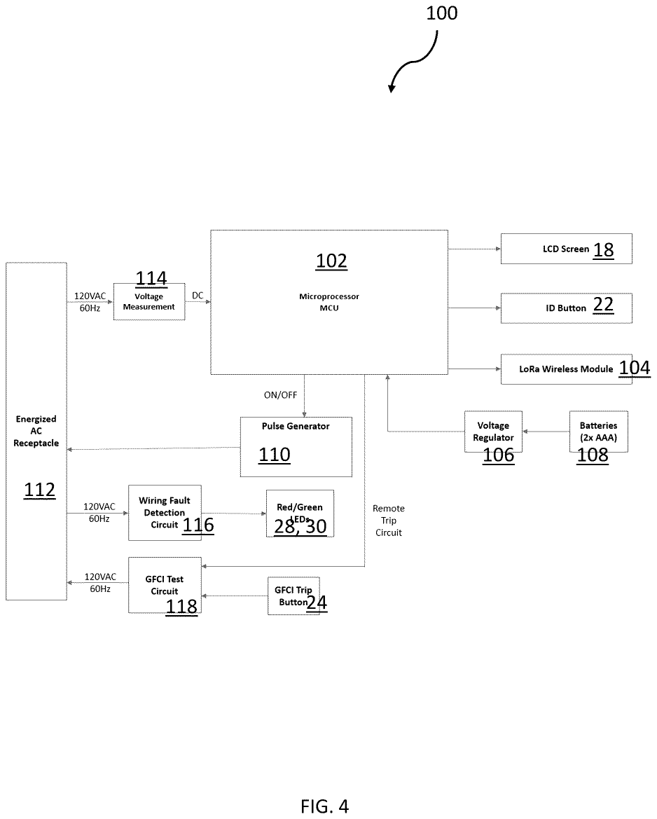

FIG. 4 shows a block diagram 100 of the transmitter 14. The transmitter includes a microprocessor 102. The microprocessor 102 is connected to the display 18, the ID buttons 22, and the wireless module 104. The microprocessor receives power through a voltage regulator 106 connected to a power source 108. The microprocessor 102 may send a signal, shown in the form of an on/off signal to the pulse generator 110. The pulse generator 110, in response to receiving a signal from the microprocessor 102, generates a pulse signal and sends the pulse signal to an energized AC receptacle 112. In the illustrated and preferred embodiment, a pulse is generated twice every sine wave (e.g., 120 Hz pulse for a 60 Hz AC signal). In other examples, other pulse frequencies may be used. The transmitter 14 includes voltage measurement circuitry 114 that may measure the voltage of the energized AC receptacle 112. The voltage measurement circuitry 114 sends a direct current (DC) signal to the microprocessor 102 indicating the measured voltage. The transmitter 14 includes a wiring fault detection circuit 116. The wiring fault detection circuit 116 may determine a circuit fault from the energized AC receptacle 112. The wiring fault detection circuit 116 is connected to indicators 28, 30 to indicate that a wiring fault has been detected. The transmitter includes a GFCI test circuit 118. The GFCI test circuit 118 may send a signal to the energized AC receptacle 112 to test the GFCI of the energized AC receptacle 112. The GFCI test circuit is connected to and may be triggered by GFCI button 24 and is connected to and may be triggered by the microprocessor 102. For example, the microprocessor 102 may trigger the GFCI test circuit 118 based on a signal received from the receiver 12.

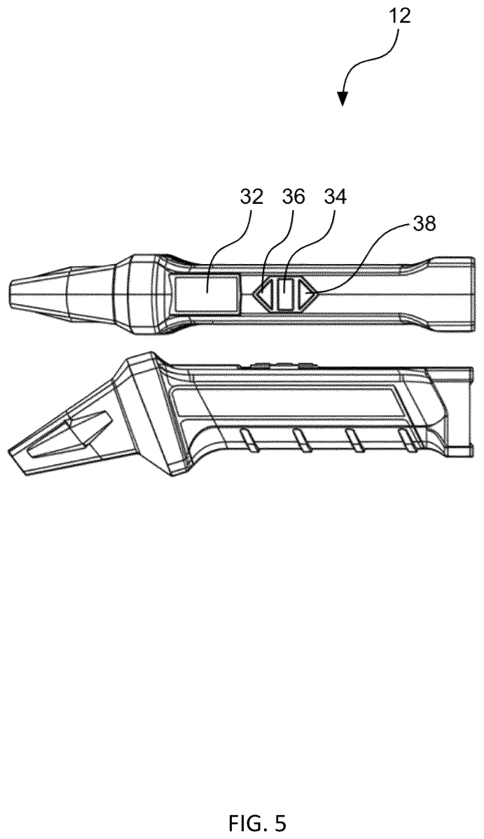

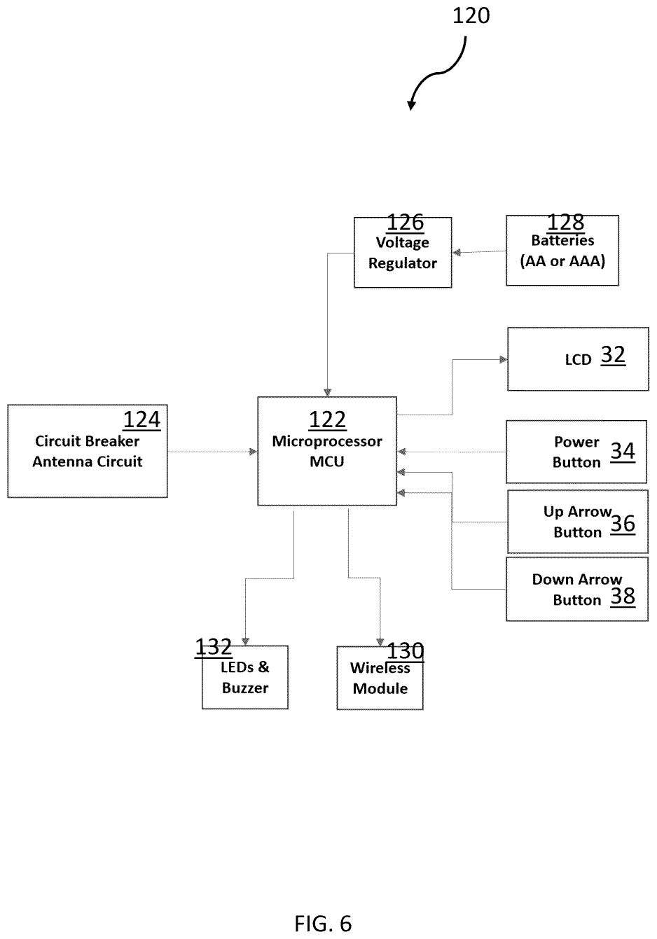

As best shown in FIGS. 5-6, the receiver 12 includes a receiver display 32. The receiver 12 includes user inputs shown in the form of a power button 34, an up button 36, and a down button 38. The receiver 12 includes a wireless module, LEDs, a buzzer, and an antenna. In the illustrated and preferred embodiment, the antenna detects the pulse signal sent by the transmitter 14 over a circuit. In the illustrated preferred embodiment, the receiver 12 may indicate to a user that the pulse signal has been detected by the LEDs, buzzer or display 32. In the preferred embodiment, the wireless module is a LoRa wireless module, but other wireless modules may be used (e.g., Wi-Fi, Bluetooth, SigFox, DASH7, NB-IoT, LTE-M, Wi-Fi HaLow, Zigbee, etc.).

In the illustrated and preferred embodiment, the wireless module of receiver 12 connects to the wireless module of the transmitter 14 to create a wireless data connection. In the illustrated and preferred embodiment, the wireless data connection is a two-way connection. The transmitter 14 may send information collected from the circuit (e.g., voltage, wiring conditions, GFCI information) to the receiver 12 over the wireless data connection. In the illustrated and preferred embodiment, the receiver 12 may display the receiver circuit information (e.g., voltage, wiring conditions, GFCI information) on the display 32. In the illustrated and preferred embodiment, the receiver 12 may send a signal to the transmitter 14, via the wireless data connection, to trip the GFCI.

FIG. 6 shows a block diagram 120 of the receiver 12. The receiver 12 includes a microprocessor 122. The microprocessor 122 is connected to and receives signals from a circuit breaker antenna circuit 124. The microprocessor 102 is connected to and may send signals to the display 32. The microprocessor 122 is connected to and may receive user inputs via the power button 34, up button 36, and down button 38. The microprocessor 122 receives power through a voltage regulator 126 connected to a power source 128. The microprocessor is connected to and may send and receive data via wireless module 130. The microprocessor 122 is connected to and may send output signals to a user via LEDs and buzzers.

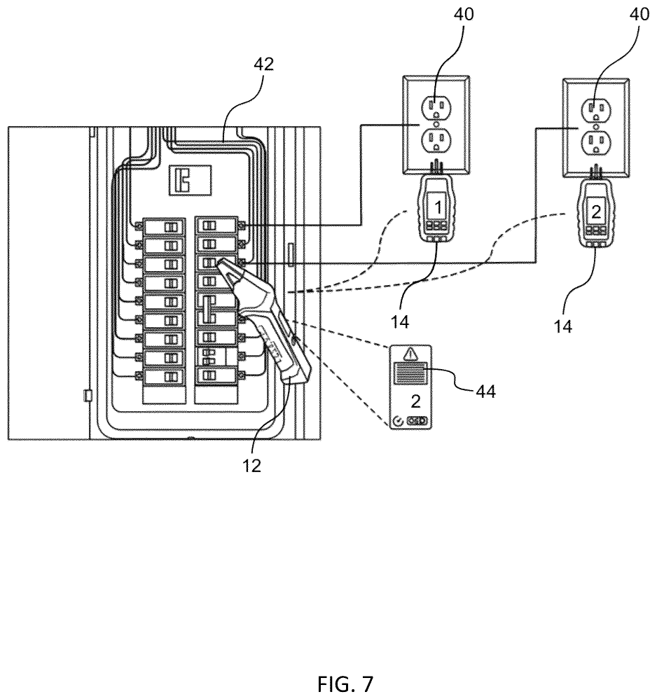

As best shown in FIG. 7, in the illustrated and preferred embodiment, the receiver 12 may connect, via the wireless module, to multiple transmitters 14. In the illustrated and preferred embodiment, a first transmitter 14 of multiple transmitters may be plugged into an outlet 40 by a user. The user may use the ID buttons 22 to set a transmitter identifier. In the illustrated and preferred embodiment, the transmitter identifier is an ID number. While any number of ID numbers may be chosen, in the illustrated and preferred embodiment, the user may set the ID number between 1 and 99. When the user has set an ID number for the transmitter 14, the transmitter 14 and receiver 12 will perform a handshake over the wireless data connection. The receiver 12 will show, on the display 32, the ID number of the connected transmitter 14. In examples where the user has multiple transmitters 14, the user may plug in a second transmitter 14 and set the second transmitter 14 to a different ID number than the first transmitter 14. The second transmitter 14 will connect to the receiver 12 over the wireless data connection. The user may use the up button 36 and the down button 38 to scroll through the various transmitters 14 that are connected to the receiver 12. The display 32 will show the ID number of the selected transmitter 14. When a transmitter 12 is selected by the receiver 12, the receiver will indicate to the transmitter 12 to send the pulse signal over the selected circuit. The user may then use the receiver 12 to detect the pulse signal. A user, for example, may pass the receiver 12 over a circuit breaker 42 (e.g., circuit breaker panel) to detect the pulse signal transmitted over the circuit by the selected transmitter 14 (e.g., first transmitter). After the circuit connected to the selected transmitter 14 (e.g., first transmitter) has been identified by the user, the user may look for a second circuit connected to the second transmitter 14. To do so, the user may use the up button 36 and/or down button 38 to select the second transmitter 14. When the second transmitter 14 is selected, the receiver 12 will send a message (over the wireless data connection) to the first transmitter 14 to stop sending the pulse signal over the connected circuit. The receiver 12 will send a signal to the second transmitter 14 to start sending a pulse signal over the circuit connected to the second transmitter 14. The user may then use the receiver 12 to detect the pulse signal in the circuit breaker 42 to identify the circuit connected to the second transmitter 14.

In the illustrated and preferred embodiment, the receiver 12 may use LEDs, speakers, buzzers, and/or the display 32 to indicate that the receiver 12 is detecting the pulse signal. As best shown in FIG. 7, the display 32 may show a signal strength 44 of the detected pulse signal. FIG. 7 shows the detected signal strength 44 of the signal detected from the transmitter 14 with transmitter identifier #2 selected.

In the illustrated and preferred embodiment, when the receiver 12 is used with multiple transmitters 14, the display 32 of the receiver 12 may show circuit information received from the selected transmitter 14 (e.g., voltage, wiring conditions, GFCI information). In some examples, the receiver 12 may send a signal to the selected transmitter 14 to test the GFCI and receive GFCI information of the connected circuit.

In some examples, the transmitter 12 will have a connection symbol or indication on, for example, the display 18 to indicate that the transmitter 12 is wirelessly connected to the receiver 14. In some examples, the connection symbol may blink when the transmitter 12 is wirelessly connected to the receiver 14. In some examples, the connection symbol may be solid when the transmitter 12 is wirelessly connected to the receiver and the transmitter is transmitting the pulse signal over the connected circuit.

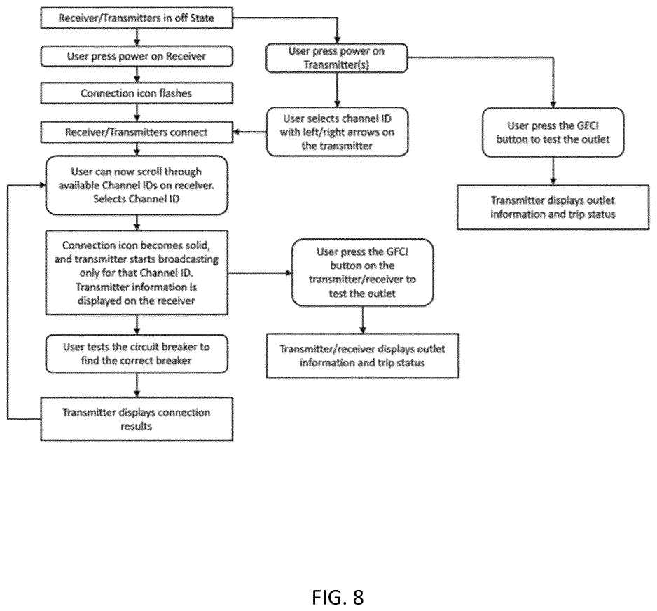

FIG. 8 is a flow chart illustrating an exemplary method for operating a multi-remote circuit breaker finder system (e.g., system 10) including a receiver 12 and one or more transmitters 14. In an example use case, the receiver 12 and the transmitter(s) 14 are initially in an off state. The receiver 12 is powered on (e.g., via power button 34), and one or more transmitters 14 are powered on (e.g., via power button 26). In response to application startup and/or discovery, a connection indicator (e.g., a connection icon presented on the transmitter display 18 and/or receiver display 32) may transition from a flashing state to indicate ongoing connection establishment to a solid state to indicate a completed wireless association between the receiver 12 and a given transmitter 14.

After a wireless association is established, a channel identifier (channel ID) is selected for at least one transmitter 14. In the illustrated workflow, channel ID selection may be performed at the transmitter 14 (e.g., using left/right arrow inputs or ID button(s) 22) and may additionally or alternatively be performed at the receiver 12 by scrolling through available channel IDs (e.g., via up arrow button 36 and down arrow button 38) and selecting a desired channel ID. Upon selection of a channel ID, the transmitter 14 may begin broadcasting (and/or responding) for the selected channel ID, and transmitter information associated with the selected channel ID may be presented on the receiver display 32. In some implementations, the receiver 12 may maintain associations with multiple transmitters 14 while designating, at a given time, one transmitter 14 as an active transmitter for circuit tracing operations.

With an active transmitter 14 selected, the user tests a circuit breaker to identify a corresponding breaker (e.g., by moving the receiver 12 proximate breakers of a breaker panel and observing an indication of detected signaling). For example, the receiver 12 may indicate a signal-strength metric corresponding to a pulse signal generated by the selected transmitter 14 and coupled onto a circuit via an energized receptacle (e.g., receptacle 40). The receiver 12 may provide the indication via the display 32 and/or via one or more additional output modalities (e.g., LEDs and/or buzzer 132). After identifying the correct breaker, the transmitter 14 may display connection results and/or other status information.

FIG. 8 further illustrates an outlet test in which a user actuates a GFCI test input (e.g., GFCI trip button 24 on a transmitter 14 and/or a corresponding receiver-side control) to test a receptacle or a GFCI-protected circuit. In response, the transmitter 14 may apply a GFCI test via an internal test circuit (e.g., GFCI test circuit 118) and present outlet information and trip status on the transmitter display 18. Additionally or alternatively, outlet information and trip status may be communicated to the receiver 12 and presented on the receiver display 32. In some implementations, the receiver 12 issues, over the wireless data connection, a command that causes the selected transmitter 14 to execute the GFCI test and return a test result for display.

Preferred embodiments of the inventive concepts are described herein, including the best mode known to the inventor(s) for carrying out the inventive concepts. Variations of those preferred embodiments will become apparent to those of ordinary skill in the art upon reading the foregoing description. The inventor(s) expect skilled artisans to employ such variations as appropriate, and the inventor(s) intend that the inventive concepts can be practiced otherwise than as specifically described herein. Accordingly, the inventive concepts disclosed herein include all modifications and equivalents of the subject matter recited in the claims appended hereto as permitted by applicable law. Moreover, any combination of the above-described elements and features in all possible variations thereof is encompassed by the inventive concepts unless otherwise indicated herein or otherwise clearly contradicted by context. Further in this regard, while highly preferred forms of the multi-remote circuit breaker finder are shown in the figures, it should be understood that this disclosure anticipates variations in the specific details of each of the disclosed components and features of the material dispenser and that no limitation to a specific form, configuration, or detail is intended unless expressly and specifically recited in an appended claim.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. The use of any and all examples, or exemplary language (e.g., “such as”) provided herein, is intended merely to better illuminate the inventive concepts disclosed herein and does not pose a limitation on the scope of any invention unless expressly claimed. No language in the specification should be construed as indicating any non-claimed element as essential to the practice of the inventive concepts disclosed herein.

1. A circuit breaker finder system comprising:
a receiver including a receiver wireless module and an antenna circuit configured to detect a signal at a circuit breaker panel; and
a plurality of transmitter devices, each transmitter device configured to couple to a receptacle and including a signal generator configured to send the signal through the receptacle onto a circuit connected to the receptacle,
wherein each transmitter device of the plurality of transmitter devices includes a transmitter wireless module configured to communicate with the receiver wireless module;
wherein the receiver is configured to communicate with the plurality of transmitter devices and to indicate detection of the signal corresponding to a selected transmitter device.

2. The system of claim 1, wherein the signal is a pulse signal.

3. The system of claim 1, wherein each transmitter device includes at least one user input configured to set a transmitter identifier for the transmitter device, and wherein the receiver is configured to display the transmitter identifier of at least one transmitter device connected to the receiver via a wireless data connection.

4. The system of claim 2, wherein the transmitter identifier is an ID number.

5. The system of claim 1, wherein the receiver includes user input buttons, and wherein the receiver is configured to scroll through transmitter identifiers of the plurality of transmitter devices connected to the receiver.

6. The system of claim 2, wherein the receiver is configured, in response to selection of a first transmitter device of the plurality of transmitter devices, to send a message to the first transmitter device to enable sending of the pulse signal over a first circuit connected to the first transmitter device.

7. The system of claim 6, wherein the receiver is configured, in response to selection of a second transmitter device of the plurality of transmitter devices, to send a message to the first transmitter device to stop sending the pulse signal over the first circuit and to send a message to the second transmitter device to start sending the pulse signal over a second circuit connected to the second transmitter device.

8. The system of claim 2, wherein the receiver includes a display and is configured to display a signal strength corresponding to a detected pulse signal.

9. The system of claim 1, wherein each transmitter device includes voltage measurement circuitry configured to measure a voltage of the receptacle and to provide a measured-voltage signal to a microprocessor of the transmitter device.

10. The system of claim 1, wherein each transmitter device includes a ground-fault circuit interrupter (GFCI) test circuit configured to provide a signal to the receptacle to test GFCI protection of the receptacle.

11. The system of claim 10, wherein each transmitter device includes a GFCI button coupled to the GFCI test circuit to trigger the GFCI test circuit.

12. The system of claim 10, wherein the receiver is configured to send a signal to a selected transmitter device via the wireless data connection, and wherein the selected transmitter device is configured to trigger the GFCI test circuit based on the signal received from the receiver.

13. The system of claim 1, wherein the receiver is configured to receive, via a two-way wireless data connection, circuit information from a selected transmitter device, and to display at least a portion of the circuit information on a receiver display.

14. The system of claim 13, wherein the circuit information includes at least one of voltage information, wiring condition information, and GFCI information.

15. The system of claim 2, wherein the receiver is configured to provide a user-notification output indicating detection of the pulse signal using at least one of a display, a light emitting diode (LED), and a buzzer.

16. The system of claim 1, wherein each transmitter device includes a transmitter display configured to display receptacle status information including at least one of voltage information, wiring condition information, and GFCI information.

17. The system of claim 2, wherein each transmitter device includes a microprocessor configured to provide an on/off control signal to the pulse generator to selectively enable and disable generation of the pulse signal.

18. A method of identifying a circuit breaker corresponding to an energized receptacle, the method comprising:
coupling a first transmitter to a first energized receptacle, the first transmitter including a pulse generator and a wireless module;
wirelessly connecting the first transmitter to a receiver including a receiver wireless module and an antenna circuit configured to detect a pulse signal at a circuit breaker panel;
using the receiver to select the first transmitter; and
in response to selecting the first transmitter, causing the first transmitter to send, via the pulse generator, a pulse signal through the first energized AC receptacle onto a circuit associated with the first energized AC receptacle;
wherein the receiver indicates detection of the pulse signal at a circuit breaker panel to identify a circuit breaker corresponding to the first energized AC receptacle.

19. The method of claim 18, further comprising coupling a second transmitter to a second energized receptacle, wirelessly connecting the second transmitter to the receiver, and selecting, via the receiver, the second transmitter while the first transmitter remains wirelessly connected to the receiver.

20. The method of claim 18, further comprising determining, at the receiver, a signal-strength metric corresponding to the detected pulse signal, and outputting, via a user-notification output of the receiver, an indication of the signal-strength metric.
